(19) United States
(12) Patent Application Publication
(10) Pub. No.: US 2026/0190388 A1
(43) Pub. Date: Jul. 2, 2026

(54) THIN FILM TRANSISTOR, AND DISPLAY APPARATUS COMPRISING THE SAME

(71) Applicant: LG Display Co., Ltd., Seoul (KR)

(72) Inventors: Min-Jae Jeong, Paju-si (KR); Jihoon Park, Paju-si (KR); KiTaeg Shin, Paju-si (KR)

(21) Appl. No.: 19/417,406

(22) Filed: Dec. 12, 2025

(30) Foreign Application Priority Data
Jan. 2, 2025 (KR) 10-2025-0000441

(51) Int. Cl. H10D 30/67; G02F 1/1368; H10D 86/40; H10D 86/60; H10K 59/121

(52) U.S. Cl. CPC H10D 30/6729; H10D 30/6757; H10D 86/481; H10D 86/60; G02F 1/1368; H10K 59/1213

(57) ABSTRACT

A thin film transistor includes: a gate electrode; an active layer disposed on the gate electrode; a drain electrode and a source electrode disposed on the active layer and spaced apart from each other; and a floating electrode disposed between the drain electrode and the source electrode. The floating electrode includes a first opening portion open toward the drain electrode and a second opening portion open toward the source electrode. The first opening portion is configured to be opened toward the drain electrode, and the second opening portion is configured to be opened toward the source electrode.

### CROSS REFERENCE TO RELATED APPLICATION

This application claims priority from and the benefit of Korean Patent Application No. 10-2025-0000441, filed on Jan. 2, 2025, which is hereby incorporated by reference for all purposes as if fully set forth herein.

### BACKGROUND

### Field

Embodiments of the invention relate generally to a thin film transistor and a display apparatus including the same.

### Discussion of the Background

Thin film transistors are widely used as switching elements or driving elements in display apparatuses such as liquid crystal display apparatuses or organic light emitting devices because they may be manufactured on glass or plastic substrates.

Thin film transistors may be formed into various structures depending on the type of material that constitutes the active layer, the arrangement structure of the electrodes (gate electrode, source electrode, drain electrode), etc.

For example, a thin film transistor with a BCE (Back Channel Etched) structure is structured so that the gate electrode may be disposed at the bottom while the source electrode and drain electrode are disposed at the top.

In particular, in a thin film transistor having the BCE structure, the source electrode and drain electrode are formed by an etching process without forming an etch stopper (ES) on the active layer. As such, the structure is generally simplified and the number of mask processes can be reduced during the manufacturing process, which may increase productivity.

Thin film transistors with this type of BCE structure are advantageous in implementing high PPI (pixels per inch), but an area where the active layer and the source/drain electrodes overlap is inevitably created.

The overlapping area of the active layer and the source/drain electrodes is affected by a parasitic capacitor generated between the gate electrode and the source/drain electrodes. This parasitic capacitor causes differences in pixel charging characteristics, resulting in luminance non-uniformity defects, which not only degrade image quality but also lead to inefficient power consumption.

Recently, ongoing research has focused on suppressing parasitic capacitors between the gate electrode and the source/drain electrodes in thin film transistors with a BCE structure.

The above information disclosed in this Background section is only for understanding of the background of the inventive concepts, and, therefore, it may contain information that does not constitute prior art.

### SUMMARY

According to one embodiment of the present invention, a thin film transistor is capable of suppressing generation of parasitic capacitors between a gate electrode and source/drain electrodes by controlling the arrangement structure of source electrodes and drain electrodes.

According to another embodiment of the present invention, a thin film transistor with improved short channel effect by controlling the arrangement structure of source electrodes and drain electrodes is provided.

According to another embodiment of the present invention, a thin film transistor in which the generation of a kick-back voltage is suppressed by controlling the arrangement structure of a source electrode and a drain electrode is provided.

According to another embodiment of the present invention, a thin film transistor in which the generation of a kick-back voltage is suppressed by further including a capacitor electrode overlapping a floating electrode is provided.

Additional features of the inventive concepts will be set forth in the description which follows, and in part will be apparent from the description, or may be learned by practice of the inventive concepts.

According to one embodiment of the present invention, a thin film transistor includes: a gate electrode; an active layer disposed on the gate electrode; a drain electrode and a source electrode disposed on the active layer and spaced apart from each other; and a floating electrode disposed between the drain electrode and the source electrode. The floating electrode includes a first opening portion open and a second opening portion. The first opening portion is configured to be opened toward the drain electrode, and the second opening portion is configured to be opened toward the source electrode.

The active layer may include a channel portion including a first channel portion disposed between the drain electrode and the first opening in a plan view; and a second channel portion disposed between the source electrode and the second opening in a plan view.

The active layer may further include a first connecting portion disposed between the first channel portion and the second channel portion, and the first connecting portion may be electrically connected with the floating electrode.

The active layer may further include a second connecting portion disposed at one side of the first channel portion and a third connecting portion disposed at one side of the second channel portion. The first channel portion may be disposed between the first connecting portion and the second connecting portion. The second channel portion may be disposed between the first connecting portion and the third connecting portion, and the second connecting portion may be electrically connected with the drain electrode, and the third connecting portion may be electrically connected with the source electrode.

In a plan view, each of the first opening and the second opening may have a U shape.

The first opening may include a first-to-first extension portion disposed toward one side of the drain electrode; and a first-to-second extension portion disposed toward the other side of the drain electrode, such that the drain electrode may be disposed between the first-to-first extension portion and the first-to-second extension portion. The second opening may include a second-to-first extension portion disposed toward one side of the source electrode; and a second-to-second extension portion disposed toward the other side of the source electrode, such that the source electrode may be disposed between the second-to-first extension portion and the second-to-second extension portion.

The first channel portion may have a first width, and the first width increases in a plane from the drain electrode to the floating electrode, and the first width may be measured in a direction perpendicular to a direction connecting the drain electrode and the floating electrode at the shortest distance.

The second channel portion may have a second width, and the second width increases in a plane from the source electrode to the floating electrode, and the second width may be measured in a direction perpendicular to the direction connecting the source electrode and the floating electrode at the shortest distance.

In a plan view, a sum of an area in which the drain electrode overlaps the active layer and an area in which the source electrode overlaps the active layer may be smaller than an area in which the floating electrode may overlap the active layer.

In a plan view, each of the first channel portion and the second channel portion may have a U shape.

Each of the drain electrode and the source electrode may have a linear shape extending along one direction.

The thin film transistor may further include a capacitor electrode that overlaps the floating electrode, and the floating electrode and the capacitor electrode may be spaced apart from each other and overlapped to form a capacitor.

The capacitor electrode may include a first capacitor electrode, and the first capacitor electrode may be disposed on the floating electrode.

The capacitor electrode may include a second capacitor electrode, and the second capacitor electrode may be disposed on the same layer as the gate electrode and spaced apart from the gate electrode.

The drain electrode, the source electrode and the floating electrode may be disposed on a same layer.

At least a portion of the gate electrode may overlap the drain electrode, the source electrode, and the floating electrode.

According to another embodiment of the present invention, a display apparatus includes one or more thin film transistors comprises a display panel including: a gate electrode; an active layer disposed on the gate electrode; a drain electrode and a source electrode disposed on the active layer and spaced apart from each other; and a floating electrode disposed between the drain electrode and the source electrode, in which the floating electrode includes a first opening portion and a second opening portion, and in which the first opening portion is configured to be opened toward the drain electrode and the second opening portion is configured to be opened toward the source electrode.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the inventive concepts.

FIG. 1 is a schematic plan view of a thin film transistor according to an embodiment of the present invention.

FIG. 2 is a schematic cross-sectional view taken along line I-I′ of FIG. 1.

FIG. 3 is a schematic plan view of a thin film transistor according to another embodiment of the present invention.

FIG. 4 is a schematic cross-sectional view taken along line II-II′ of FIG. 3.

FIG. 5 is a schematic plan view of a thin film transistor according to still another embodiment of the present invention.

FIG. 6 is a schematic cross-sectional view taken along line III-III′ of FIG. 5.

FIG. 7 is a schematic circuit diagram of a thin film transistor according to an embodiment of the present invention.

FIG. 8 is a schematic circuit diagram of a thin film transistor according to another embodiment of the present invention.

FIG. 9 is a schematic view of a display apparatus according to still another embodiment of the present invention.

FIG. 10 is a schematic view of one pixel (P) of FIG. 9.

FIG. 11 is a schematic circuit diagram of one pixel of another display apparatus according to an embodiment of the present invention.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the D1-axis, the D2-axis, and the D3-axis are not limited to three axes of a rectangular coordinate system, such as the x, y, and z-axes, and may be interpreted in a broader sense. For example, the D1-axis, the D2-axis, and the D3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

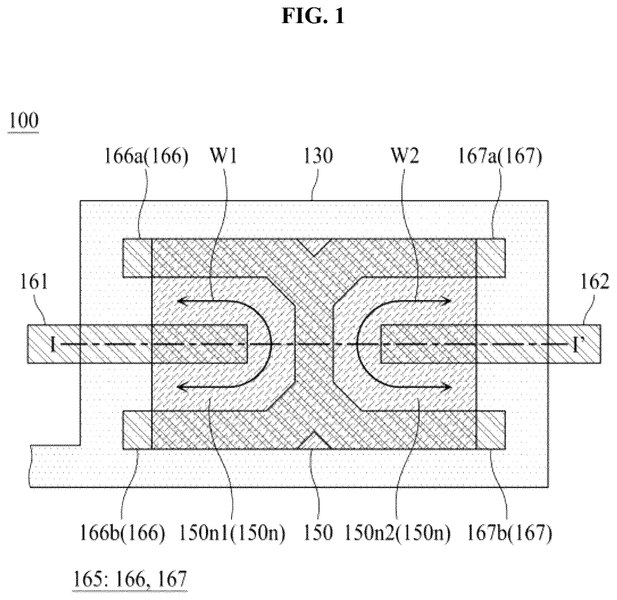

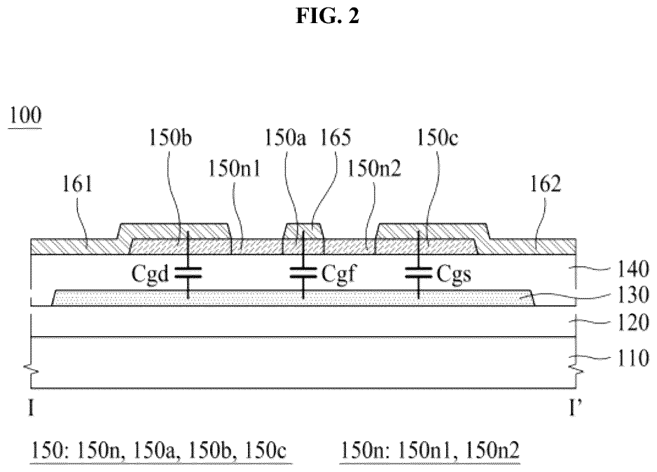

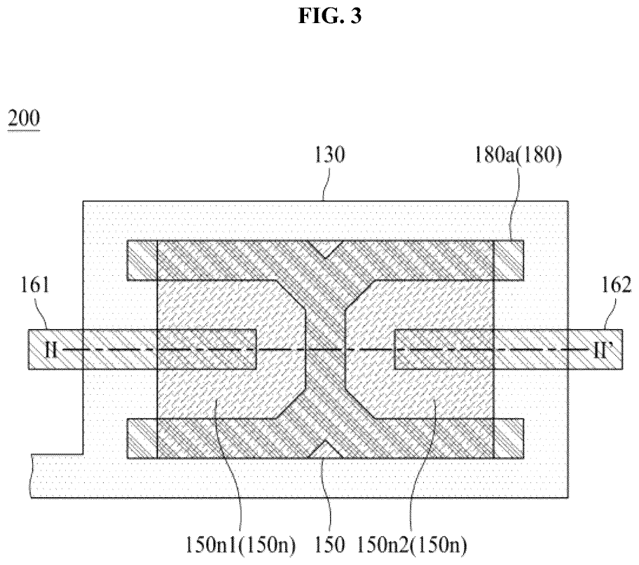

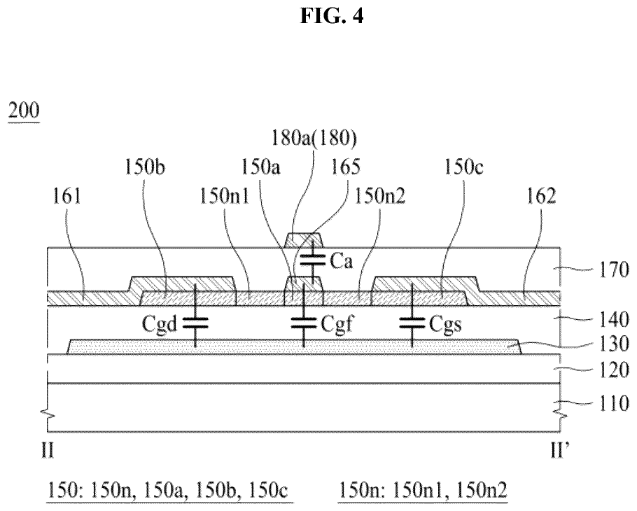

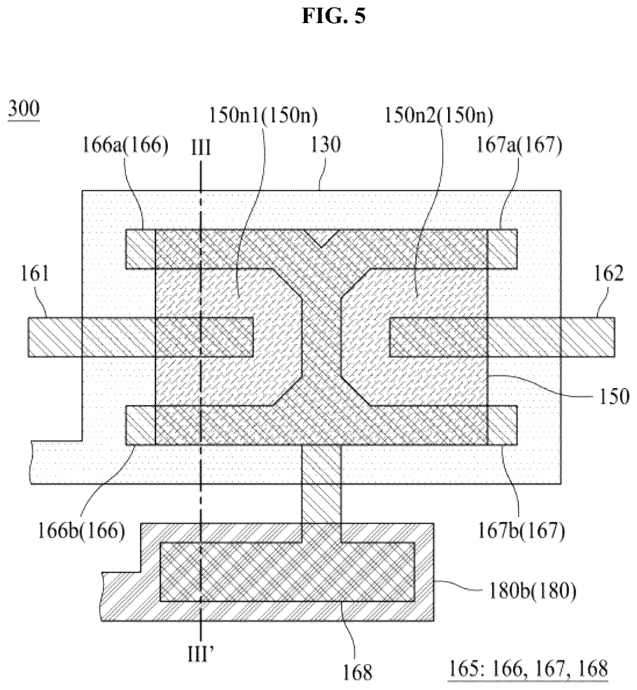

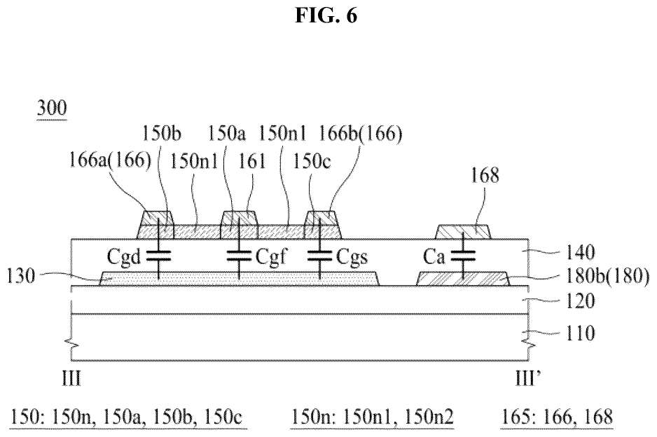

FIG. 1 is a schematic plan view of a thin film transistor (100) according to one embodiment of the present invention. FIG. 2 is a schematic cross-sectional view taken along line I-I′ of FIG. 1. FIG. 3 is a schematic plan view of a thin film transistor (200) according to another embodiment of the present invention. FIG. 4 is a schematic cross-sectional view taken along line II-II′ of FIG. 3. FIG. 5 is a schematic plan view of a thin film transistor (300) according to another embodiment of the present invention. FIG. 6 is a schematic cross-sectional view taken along line III-III′ of FIG. 5.

Thin film transistor (100) according to one embodiment of the present invention may include a gate electrode (130), an active layer (150), a drain electrode (161), a source electrode (162), and a floating electrode (165).

The components of the thin film transistor (100) are described in detail below.

Glass or plastic may be used as the base substrate (110). A transparent plastic having flexible properties, such as polyimide, may be used as the plastic.

A light-blocking layer (not shown) may be disposed on the base substrate (110). The light-blocking layer (not shown) may block light incident from the base substrate (110) and may protect the active layer (150). If another structure serves as a light blocking structure, the light-blocking layer (not shown) may be omitted.

According to one embodiment of the present invention, a buffer layer (120) may be disposed on a base substrate (110). FIG. 2 illustrates a buffer layer (120) disposed on a base substrate (110).

The buffer layer (120) may have insulating properties and protect the active layer (150). The buffer layer (120) may include at least one of silicon oxide (SiOₓ), silicon nitride (SiNₓ), and metal oxide having insulating properties.

Although FIG. 2 illustrates a buffer layer (120) as a single layer, the inventive concepts are not limited thereto, and may include multiple layers in other embodiments. In addition, another layer may be disposed between the base substrate (110) and the buffer layer (120), and another layer may be disposed between the buffer layer (120) and the gate electrode (130) in some embodiments.

According to one embodiment of the present invention, the gate electrode (130) may be disposed on the buffer layer (120).

According to one embodiment of the present invention, a portion of the gate electrode (130) may overlap the active layer (150). For example, referring to FIG. 1, the gate electrode (130) may overlap the entire area of the active layer (150).

The gate electrode (130) may include at least one of an aluminum series metal such as aluminum (Al) or an aluminum alloy, a silver series metal such as silver (Ag) or a silver alloy, a copper series metal such as copper (Cu) or a copper alloy, a molybdenum series metal such as molybdenum (Mo) or a molybdenum alloy, chromium (Cr), tantalum (Ta), neodymium (Nd), and titanium (Ti). The gate electrode (130) may also have a multilayer film structure including at least two conductive films having different physical properties.

According to one embodiment of the present invention, a gate insulating film (140) may be disposed on the gate electrode (130). Specifically, the gate insulating film (140) may be interposed between the gate electrode (130) and the active layer (150) in a thickness direction.

According to one embodiment of the present invention, the gate insulating film (140) may cover the upper surface of the gate electrode (130). In particular, the gate insulating film (140) may cover the entity of the upper surface of the gate electrode (130). FIG. 2 illustrates an example in which the gate insulating film (140) covers the entire upper surface of the gate electrode (130).

The gate insulating film (140) may include at least one of silicon oxide, silicon nitride, and metal oxide. The gate insulating film (140) may have a single-film structure or a multilayer film structure. The gate insulating film (140) may protect the active layer (150).

According to one embodiment of the present invention, an active layer (150) may be disposed on the gate insulating film (140). Specifically, the active layer (150) may be disposed on the gate electrode (130) and may overlap the gate electrode (130) in the thickness direction.

According to one embodiment of the present invention, the active layer (150) may include a channel portion (150n). Specifically, the channel portion (150n) may include a first channel portion (150n1) and a second channel portion (150n2).

Referring to FIG. 1, the first channel portion (150n1) may be disposed between the drain electrode (161) and the floating electrode (165) in a plan view, and the second channel portion (150n2) may be disposed between the source electrode (162) and the floating electrode (165) in a plan view.

According to one embodiment of the present invention, the active layer (150) may further include a first connecting portion (150a) disposed between a first channel portion (150n1) and a second channel portion (150n2), a second connecting portion (150b) disposed at one side of the first channel portion (150n1), and a third connecting portion (150c) disposed at one side of the second channel portion (150n2).

For example, referring to FIGS. 1 and 2, the first connecting portion (150a) may be disposed between the first channel portion (150n1) and the second channel portion (150n2) and may be electrically connected with the floating electrode (165). In this case, the floating electrode (165) may cover the entirety of the first connecting portion (150a), without being limited thereto. The first channel portion (150n1) may be disposed between the first connecting portion (150a) and the second connecting portion (150b), and the second channel portion (150n2) may be disposed between the first connecting portion (150a) and the third connecting portion (150c). The second connecting portion (150b) may be electrically connected with the drain electrode (161), and the third connecting portion (150c) may be electrically connected with the source electrode (162). In this case, the drain electrode (161) may partially cover the second connecting portion (150b), and the source electrode (162) may partially cover the third connecting portion (150c), without being limited thereto.

For example, the first connecting portion (150a) may overlap the floating electrode (165) in the thickness direction, the second connecting portion (150b) may overlap the drain electrode (161) in the thickness direction, and the third connecting portion (150c) may overlap the source electrode (162) in the thickness direction.

The floating electrode (165) may form an ohmic contact with the first connecting portion (150a), and the drain electrode (161) and the source electrode (162) may form ohmic contacts with the second connecting portion (150b) and the third connecting portion (150c), respectively.

According to one embodiment of the present invention, the active layer (150) may be made of any one of an oxide semiconductor material, low temperature polycrystalline silicon (LTPS), and amorphous silicon (A-Si).

According to one embodiment of the present invention, a drain electrode (161), a source electrode (162), and a floating electrode (165) may be disposed on the active layer (150).

According to one embodiment of the present invention, the drain electrode (161) and the source electrode (162) may be disposed spaced apart from each other. For example, the floating electrode (165) may be disposed between the drain electrode (161) and the source electrode (162). The drain electrode (161), the source electrode (162), and the floating electrode (165) may be disposed on the same layer.

According to one embodiment of the present invention, each of the drain electrode (161), the source electrode (162), and the floating electrode (165) may include at least one of molybdenum (Mo), aluminum (Al), chromium (Cr), gold (Au), titanium (Ti), nickel (Ni), neodymium (Nd), copper (Cu), or an alloy thereof.

According to one embodiment of the present invention, the floating electrode (165) may be in a floating state. According to one embodiment of the present invention, the floating state may mean a state in which a component is not electrically connected to another component. The floating electrode (165) being in a floating state may mean a state in which the floating electrode (165) is not electrically connected to another component and is electrically isolated.

According to one embodiment of the present invention, a portion of the floating electrode (165) may overlap the active layer (150) in a plan view. However, at least a portion of the floating electrode (165) may not overlap the active layer (150). In addition, at least a portion of the drain electrode (161) and at least a portion of the source electrode (162) may overlap the active layer (150) in a plan view. However, a portion of the drain electrode (161) and a portion of the source electrode (162) may not overlap the active layer (150) in a plan view.

According to one embodiment of the present invention, the floating electrode (165) may include a first opening portion (166) opened (or exposed) toward the drain electrode (161) and a second opening portion (167) opened (or exposed) toward the source electrode (162).

According to one embodiment of the present invention, each of the first opening portion (166) and the second opening portion (167) may have a U shape. Specifically, the first opening portion (166) may have a U shape rotated 90 degrees counterclockwise, and the second opening portion (167) may have a U shape rotated 90 degrees clockwise.

For example, referring to FIG. 1, the drain electrode (161) may be disposed within an area opened (or exposed) by the first opening portion (166). Additionally, the source electrode (162) may be disposed within an area opened (or exposed) by the second opening portion (167). For example, the drain electrode (161) may be disposed within a region surrounded by the first opening portion (166), and the source electrode (162) may be disposed within a region surrounded by the second opening portion (167).

According to one embodiment of the present invention, each of the drain electrode (161) and the source electrode (162) may have a linear shape or straight-line shape extending along one direction.

For example, referring to FIG. 1, the first channel portion (150n1) may be disposed between the drain electrode (161) and the first opening portion (166) in a plan view. In addition, the second channel portion (150n2) may be disposed between the source electrode (162) and the second opening portion (166) in a plan view.

According to one embodiment of the present invention, the first opening portion (166) may include a first-first extension portion (166a) disposed toward one side of the drain electrode (161) and a first-second extension portion (166b) disposed toward the other side of the drain electrode (161). For example, referring to FIG. 1, the drain electrode (161) may be disposed between the first-first extension portion (166a) and the first-second extension portion (166b).

According to one embodiment of the present invention, the second opening portion (167) may include a second-first extension portion (167a) disposed toward one side of the source electrode (162) and a second-second extension portion (167b) disposed toward the other side of the source electrode (162). For example, referring to FIG. 1, the source electrode (162) may be disposed between the second-first extension portion (167a) and the second-second extension portion (167b).

According to one embodiment of the present invention, at least a portion of the gate electrode (130) may overlap the drain electrode (161), the source electrode (162), and the floating electrode (165).

In general, in a thin film transistor with a BCE (Back Channel Etched) structure in which the gate electrode may be disposed below and the active layer may be disposed above, an overlapping region between the active layer and the drain and source electrodes is inevitably generated.

The overlapping region of the active layer and the drain electrode and source electrode is affected by the parasitic capacitor (Cgd) generated between the gate electrode and the drain electrode and the parasitic capacitor (Cgs) generated between the gate electrode and the source electrode, which may cause differences in pixel charging characteristics and result in luminance unevenness defects.

In general, when the source electrode is formed in a U-shape, the size of the parasitic capacitor (Cgs) generated between the gate electrode and the source electrode may be larger than the parasitic capacitor (Cgd) generated between the gate electrode and the drain electrode. As a result, the voltage change applied to the gate electrode may be transmitted slowly, which may prevent the thin film transistor from turning on or off quickly.

In addition, when the size of the source electrode is reduced to reduce the size of the parasitic capacitor (Cgs) that is generated between the gate electrode and the source electrode, the gap between the drain electrode and the source electrode may be narrow, and the channel length may shorten. As a result, problems such as leakage current due to the short channel effect may occur.

According to one embodiment of the present invention, when the drain electrode (161) and the source electrode (162) are formed in a linear shape rather than a U-shape, the parasitic capacitor (Cgd) generated between the gate electrode (130) and the drain electrode (161) and the parasitic capacitor (Cgs) generated between the gate electrode (130) and the source electrode (162) may be reduced. For example, the sum of the area of the region where the drain electrode (161) and the active layer (150) overlap in a plane and the area of the region where the source electrode (162) and the active layer (150) overlap may be smaller than the area of the region where the floating electrode (165) and the active layer (150) overlap.

In addition, according to one embodiment of the present invention, since the first opening portion (166) and the second opening portion (167) of the floating electrode (165) are each formed in a U-shape, the movement path of carriers between the drain electrode (161) and the first opening portion (166) and between the source electrode (162) and the second opening portion (167) may be formed wider, thereby preventing device problems due to the short channel effect.

According to one embodiment of the present invention, the floating electrode (165) may need to include only the first opening portion (166) and the second opening portion (167). In other words, the floating electrode (165) may include the integrated first opening portion (166) and the second opening portion (167), and may not include any additional electrodes. In other words, the area occupied by the floating electrode (165) may need to be minimized.

For example, a parasitic capacitor (Cgf) generated between the floating electrode (165) and the gate electrode (130) may cause a kick-back voltage. The kick-back voltage may refer to a phenomenon in which the voltage momentarily jumps during a switching operation. Such voltage fluctuations may affect the picture quality of the display or damage data stored in pixels. As more charges are stored and discharged during switching of the thin film transistor due to the parasitic capacitor (Cgf) generated between the floating electrode (165) and the gate electrode (130), the voltage fluctuation range may increase, and accordingly, the magnitude of the kick-back voltage may also increase.

According to one embodiment the present invention, by including the first opening portion (166) and the second opening portion (167) that are integrated with the floating electrode (165), an area occupied by the floating electrode (165) may be minimized. As a result, a parasitic capacitor (Cgf) generated between the floating electrode (165) and the gate electrode (130) may be reduced, and the occurrence of a kick-back voltage may be suppressed.

In addition, when the parasitic capacitor between the gate electrode (130) and the drain electrode (161) and the parasitic capacitor generated between the gate electrode (130) and the source electrode (162) increase, the panel load may increase. The panel load may refer to the electrical load that the display panel applies to the driving circuit. The panel load may include the influence of electrodes, wiring, parasitic capacitors, and resistance within the panel on the driving circuit. As the panel load increases, the driving circuit may consume more power, which causes problems such as a decrease in power efficiency and a slow response speed of the panel.

According to one embodiment the present invention, since the thin film transistor (100) includes a floating electrode (165), the parasitic capacitor (Cgd) generated between the gate electrode (130) and the drain electrode (161) and the parasitic capacitor (Cgs) generated between the gate electrode (130) and the source electrode (162) may be reduced, and the panel load may be reduced.

According to one embodiment of the present invention, the first channel portion (150n1) may have a first width (W1), and the second channel portion (150n2) may have a second width (W2). In this case, the first width (W1) may be measured in a direction perpendicular to the direction connecting the drain electrode (161) and the floating electrode (165) with the shortest distance. The second width (W2) may be measured in a direction perpendicular to the direction connecting the source electrode (162) and the floating electrode (165) with the shortest distance (see FIG. 1).

According to one embodiment of the present invention, the first width (W1) in a plan view may become longer as it goes from the drain electrode (161) to the floating electrode (165). For example, the first width (W1) in a plan view may become shorter as it goes from the floating electrode (165) to the drain electrode (161).

According to one embodiment of the present invention, the second width (W2) in a plan view may become longer as it goes from the source electrode (162) to the floating electrode (165). For example, the second width (W2) in a plan view may become shorter as it goes from the floating electrode (165) to the source electrode (161).

According to one embodiment of the present invention, each of the first channel portion (150n1) and the second channel portion (150n2) may have a U shape. For example, the first channel portion (150n1) may have a U shape rotated 90 degrees counterclockwise, and the second channel portion (150n2) may have a U shape rotated 90 degrees clockwise.

When the first width (W1) and the second width (W2) become longer from the drain electrode (161) and the source electrode (162), respectively, to the floating electrode (165), the path for movement of carriers may be formed wide, thereby preventing overheating due to concentration of carriers.

According to one embodiment of the present invention, the active layer (150) may be larger than the floating electrode (165) based on the direction connecting the drain electrode (161) and the source electrode (162) with the shortest distance. In FIG. 1, the active layer (150) may be illustrated as being smaller than the floating electrode (165) based on the direction connecting the drain electrode (161) and the source electrode (162) with the shortest distance, but the inventive concepts are not limited thereto, and the active layer (150) may be larger than the floating electrode (165) in some embodiments.

According to one embodiment of the present invention, the thin film transistor (200, 300) may further include a capacitor electrode (180) overlapping the floating electrode (165) in the thickness direction. Referring to FIGS. 3, 4, 5, and 6, the floating electrode (165) and the capacitor electrode (180) may be spaced apart from and overlap each other to form a capacitor (Ca).

Referring to FIGS. 3 and 4, the capacitor electrode (180) may include a first capacitor electrode (180a) disposed on the floating electrode (165). Specifically, the first capacitor electrode (180a) may be disposed on an interlayer insulating film (170).

The interlayer insulating film (170) may be an insulating layer made of an insulating material. Specifically, the interlayer insulating film (170) may be made of an organic material, an inorganic material, or a laminate of an organic material layer and an inorganic material layer.

In a plan view, the first capacitor electrode (180a) may overlap the floating electrode (165).

Referring to FIGS. 5 and 6, the capacitor electrode (180) may include a second capacitor electrode (180b) disposed on the same layer as the gate electrode (130). The second capacitor electrode (180b) may be disposed spaced apart from the gate electrode (130). For example, the gate insulating film (140) may be disposed between the floating electrode (165) and the gate electrode (130). Specifically, the floating electrode (165) may further include a third extension portion (168) overlapping the second capacitor electrode (180b). The gate insulating film (140) may be disposed between the third extension portion (168) of the floating electrode (165) and the second capacitor electrode (180b).

As described above, the parasitic capacitor (Cgf) generated between the drain electrode (161) and the gate electrode (130) may cause a kick-back voltage. In response to this, by further disposing the capacitor electrode (180), a capacitor (Ca) generated between the floating electrode (165) and the capacitor electrode (180) may be formed. The capacitor (Ca) generated between the third extension portion (168) and the capacitor electrode (180) may act as a decoupling capacitor for the parasitic capacitor (Cgf) and compensate for the parasitic capacitor (Cgf). As a result, the generation of the kick-back voltage may be suppressed.

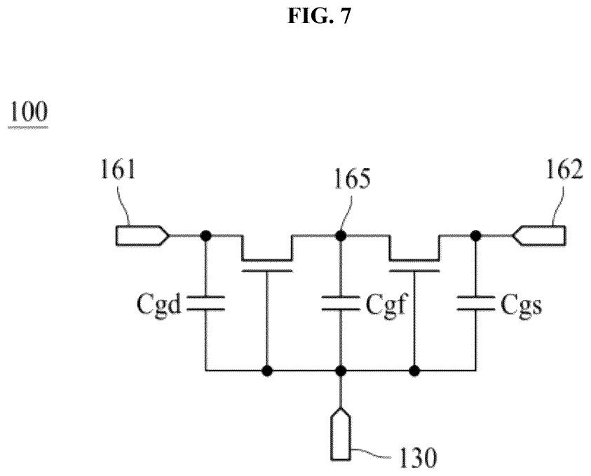

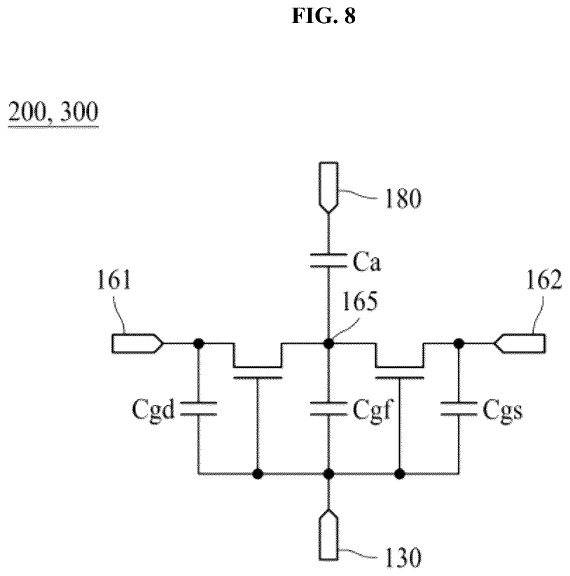

FIG. 7 is a schematic circuit diagram of a thin film transistor (100) according to one embodiment of the present invention. FIG. 8 is a schematic circuit diagram of a thin film transistor (200, 300) according to another embodiment of the present invention.

The transistor illustrated in FIG. 7 may correspond to the thin film transistor (100) illustrated in FIGS. 1 and 2, and the transistor illustrated in FIG. 8 may correspond to the thin film transistor (200, 300) illustrated in FIGS. 3, 4, 5, and 6.

Referring to FIG. 7, the thin film transistor (100) may include a gate electrode (130), a drain electrode (161), a source electrode (162), and a floating electrode (165). The gate electrode (130), the drain electrode (161), the source electrode (162), and the floating electrode (165) of FIG. 7 may correspond to the gate electrode (130), the drain electrode (161), the source electrode (162), and the floating electrode (165) illustrated in FIGS. 1 and 2, respectively. Referring to FIG. 7, parasitic capacitors (Cgd, Cgs, Cgf) may be formed between the gate electrode (130) and the drain electrode (161), between the gate electrode (130) and the source electrode (161), and between the gate electrode (130) and the floating electrode (165), respectively. The parasitic capacitors (Cgd, Cgs, Cgf) illustrated in FIG. 7 may correspond to the parasitic capacitors (Cgd, Cgs, Cgf) illustrated in FIGS. 1 and 2.

Referring to FIG. 8, the thin film transistor (200, 300) may further include a capacitor electrode (180). Referring to FIG. 8, a capacitor (Ca) may be formed between the floating electrode (165) and the capacitor electrode (180). The capacitor (Ca) illustrated in FIG. 8 may correspond to the capacitor (Ca) illustrated in FIGS. 3, 4, 5, and 6.

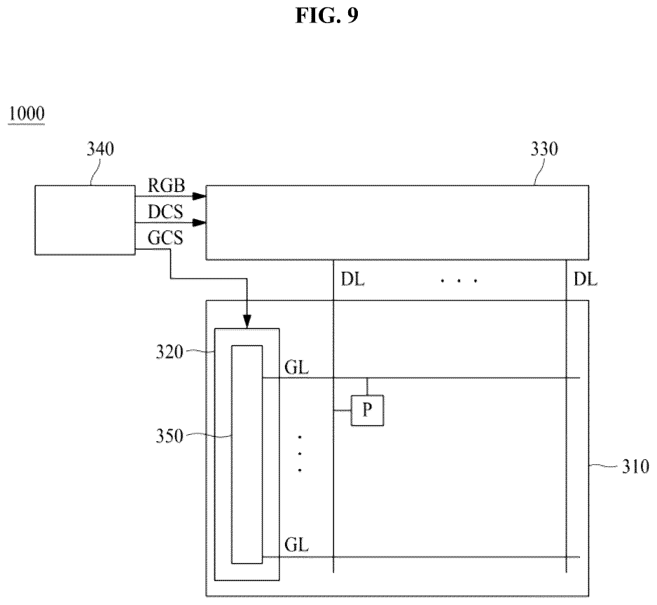

FIG. 9 is a schematic diagram of a display apparatus (1000) according to another embodiment of the present invention.

A display apparatus (1000) according to another embodiment of the present invention may include a display panel (310), a gate driver (320), a data driver (330), and a control unit (340), as illustrated in FIG. 9.

The display panel (310) may include gate lines (GL) and data lines (DL), and pixels (P) are disposed at the intersections of the gate lines (GL) and the data lines (DL). An image is displayed by driving the pixels (P). The gate lines (GL), data lines (DL), and pixels (P) may be disposed on a base substrate (110).

The control unit (340) may control the gate driver (320) and the data driver (330).

The control unit (340) may use a signal supplied from an external system (not shown) configured to output a gate control signal (GCS) for controlling the gate driver (320) and a data control signal (DCS) for controlling the data driver (330). In addition, the control unit (340) may sample input image data input from the external system, rearrange it, and supply the redisposed digital image data (RGB) to the data driver (330).

The gate control signal (GCS) may include a gate start pulse (GSP), a gate shift clock (GSC), a gate output enable signal (GOE), a start signal (Vst), and a gate clock (GCLK). In addition, the gate control signal (GCS) may include control signals for controlling a shift register.

The data control signal (DCS) may include a source start pulse (SSP), a source shift clock signal (SSC), a source output enable signal (SOE), and a polarity control signal (POL).

The data driver (330) may supply data voltage to the data lines (DL) of the display panel (310). Specifically, the data driver (330) may convert image data (RGB) input from the control unit (340) into analog data voltage and may supply the data voltage to the data lines (DL).

According to one embodiment of the present invention, the gate driver (320) may be mounted on the display panel (310). In this way, a structure in which the gate driver (320) is directly mounted on the display panel (310) may be called a Gate In Panel (GIP) structure. Specifically, in the Gate In Panel (GIP) structure, the gate driver (320) may be disposed on the base substrate (110).

A display apparatus (1000) according to one embodiment of the present invention may include at least one or more of the thin film transistors (100, 200, 300) described above.

The gate driver (320) may include a shift register (350).

The shift register (350) sequentially may supply gate pulses to the gate lines (GL) for one frame using a start signal and a gate clock transmitted from the control unit (340). Here, one frame may refer to a period during which one image is output through the display panel (310). The gate pulse may have a turn-on voltage capable of turning on a switching element (thin film transistor) disposed in a pixel (P).

Additionally, the shift register (350) may supply a gate-off signal capable of turning off the switching element to the gate line (GL) during the remaining period during which the gate pulse is not supplied during one frame. Hereinafter, the gate pulse and the gate-off signal may be collectively referred to as a scan signal (SS or Scan).

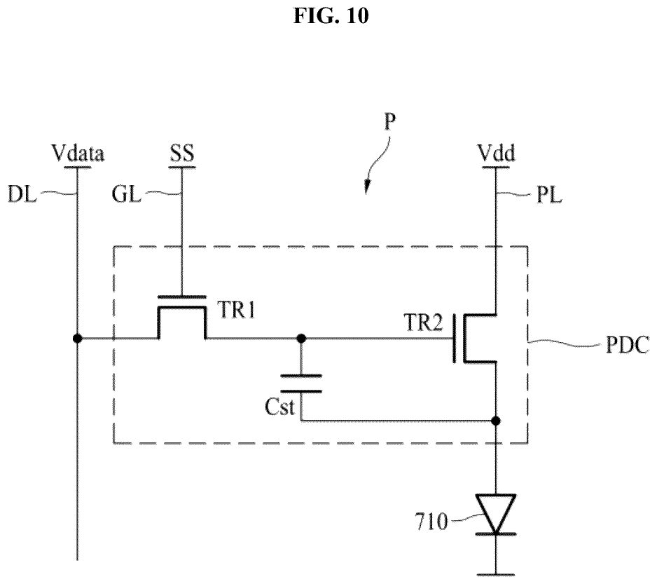

FIG. 10 is a schematic circuit diagram for one pixel (P) of FIG. 9.

The circuit diagram of FIG. 10 is an equivalent circuit diagram for a pixel (P) of a display apparatus (1000) including an organic light-emitting diode (OLED) as a display element (710).

Referring to FIG. 10, a pixel (P) may include a display element (710) and a pixel driving circuit (PDC) that drives the display element (710). Specifically, a display apparatus (1000) according to one embodiment of the present invention may include a pixel driving circuit (PDC) on a base substrate (110).

The pixel driving circuit (PDC) of FIG. 10 may include a first thin film transistor (TR1) which is a switching transistor and a second thin film transistor (TR2) which is a driving transistor. The first thin film transistor (TR1) which is a switching transistor may include a thin film transistor (100, 200, 300) according to one embodiment the present invention. In addition, the second thin film transistor (TR2) which is a driving transistor may include a thin film transistor (100, 200, 300) according to one embodiment the present invention.

The first thin film transistor (TR1) may be electrically connected to a gate line (GL) and a data line (DL), and may be turned on or off by a scan signal (SS) supplied through the gate line (GL).

The data line (DL) may provide a data voltage (Vdata) to the pixel driver circuit (PDC), and the first thin film transistor (TR1) control the application of the data voltage (Vdata).

The driving power line (PL) may provide a driving voltage (Vdd) to the display element (710), and the first thin film transistor (TR1) control the driving voltage (Vdd). The driving voltage (Vdd) may be a pixel driving voltage for driving the organic light-emitting diode (OLED), which is the display element (710).

When the first thin film transistor (TR1) is turned on by a scan signal (SS) applied through the gate line (GL) from the gate driver (320), the data voltage (Vdata) supplied through the data line (DL) may be supplied to the gate electrode of the second thin film transistor (TR2) connected to the display element (710). The data voltage (Vdata) may be charged in the storage capacitor (C1) formed between the gate electrode and the source electrode of the second thin film transistor (TR2).

The amount of current supplied to the organic light-emitting diode (OLED), which is the display element (710), through the second thin film transistor (TR2) is controlled according to the data voltage (Vdata), and accordingly, a gray level of light emitted from the display element (710) may be controlled.

The pixel driving circuit (PDC) according to another embodiment of the present invention may be formed in various structures other than the structures described above. The pixel driving circuit (PDC) may include, for example, three or more thin film transistors.

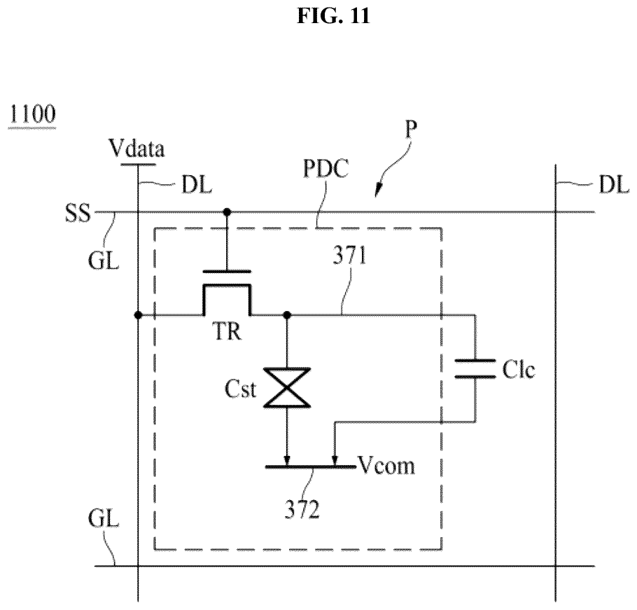

FIG. 11 is a schematic circuit diagram for one pixel of a display apparatus (1100) according to another embodiment of the present invention.

The pixel (P) of the display apparatus (1100) illustrated in FIG. 11 includes a pixel driving circuit (PDC) and a liquid crystal capacitor (Clc) connected to the pixel driving circuit (PDC). The liquid crystal capacitor (Clc) corresponds to a display element. The display apparatus (1100) of FIG. 11 is a liquid crystal display apparatus.

The pixel driving circuit (PDC) may include a thin film transistor (TR) connected to a gate line (GL) and a data line (DL), a pixel electrode (371) electrically connected to the thin film transistor (TR), a common electrode (372) opposing the pixel electrode (371), and a storage capacitor (Cst) electrically connected between the thin film transistor (TR) and the common electrode (372). A liquid crystal capacitor (Clc) may be electrically connected in parallel with the storage capacitor (Cst) between the thin film transistor (TR) and the common electrode (372).

The liquid crystal capacitor (Clc) may charge the difference voltage between the data signal supplied to the pixel electrode (371) through the thin film transistor (TR) and the common voltage (Vcom) supplied to the common electrode (372), and drive the liquid crystal according to the charged voltage to control the amount of light transmittance. The storage capacitor (Cst) stably may maintain the voltage charged to the liquid crystal capacitor (Clc).

The display apparatus (1100) according to another embodiment of the present invention may include at least one of the thin film transistors (100, 200, 300) described above.

According to embodiments of the present invention, the following advantageous effects may be obtained.

A thin film transistor according to one embodiment of the present invention may suppress the occurrence of parasitic capacitors between the gate electrode and the source/drain electrodes by controlling the arrangement structure of the source electrode and the drain electrode.

A thin film transistor according to another embodiment of the present invention may improve the short channel effect by controlling the arrangement structure of the source electrode and the drain electrode.

According to another embodiment of the present invention, a thin film transistor may reduce panel load or suppress the occurrence of kick-back voltage by controlling the arrangement structure of source electrodes and drain electrodes.

According to another embodiment of the present invention, a thin film transistor further may include a capacitor electrode overlapping a floating electrode, thereby suppressing the occurrence of a kick-back voltage.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A thin film transistor comprising:
a gate electrode;
an active layer disposed on the gate electrode;
a drain electrode and a source electrode disposed on the active layer and spaced apart from each other; and
a floating electrode disposed between the drain electrode and the source electrode,
wherein the floating electrode includes a first opening portion and a second opening portion, and
wherein the first opening portion is configured to be opened toward the drain electrode, and the second opening portion is configured to be opened toward the source electrode.

2. The thin film transistor of claim 1, wherein the active layer includes a channel portion including:
a first channel portion disposed, in a plan view, between the drain electrode and the first opening portion; and
a second channel portion disposed, in a plan view, between the source electrode and the second opening portion.

3. The thin film transistor of claim 2, wherein the active layer further includes a first connecting portion disposed between the first channel portion and the second channel portion, and the first connecting portion is electrically connected with the floating electrode.

4. The thin film transistor of claim 3,
wherein the active layer further includes a second connecting portion disposed at one side of the first channel portion and a third connecting portion disposed at one side of the second channel portion,
wherein the first channel portion is disposed between the first connecting portion and the second connecting portion, the second channel portion is disposed between the first connecting portion and the third connecting portion, and
wherein the second connecting portion is electrically connected with the drain electrode, and the third connecting portion is electrically connected with the source electrode.

5. The thin film transistor of claim 1, wherein, in a plan view, each of the first opening portion and the second opening portion has a U shape.

6. The thin film transistor of claim 1,
wherein the first opening portion includes:
a first-to-first extension portion disposed toward one side of the drain electrode; and
a first-to-second extension portion disposed toward the other side of the drain electrode, such that the drain electrode is disposed between the first-to-first extension portion and the first-to-second extension portion, and
wherein the second opening portion includes:
a second-to-first extension portion disposed toward one side of the source electrode; and
a second-to-second extension portion disposed toward the other side of the source electrode, such that the source electrode is disposed between the second-to-first extension portion and the second-to-second extension portion.

7. The thin film transistor of claim 2,
wherein the first channel portion has a first width, the first width increases, in a plan view, from the drain electrode toward the floating electrode, and
wherein the first width is measured in a direction perpendicular to a direction connecting the drain electrode and the floating electrode at a shortest distance.

8. The thin film transistor of claim 2,
wherein the second channel portion has a second width, the second width increases, in a plan view, from the source electrode toward the floating electrode, and
wherein the second width is measured in a direction perpendicular to a direction connecting the source electrode and the floating electrode at a shortest distance.

9. The thin film transistor of claim 1, wherein, in a plan view, a sum of an area in which the drain electrode overlaps the active layer and an area in which the source electrode overlaps the active layer is smaller than an area in which the floating electrode overlaps the active layer.

10. The thin film transistor of claim 2, wherein, in a plan view, each of the first channel portion and the second channel portion has a U shape.

11. The thin film transistor of claim 1, wherein each of the drain electrode and the source electrode has a linear shape extending along one direction.

12. The thin film transistor of claim 1, further comprising a capacitor electrode overlapping the floating electrode,
wherein the floating electrode and the capacitor electrode are spaced apart from and overlap each other to form a capacitor.

13. The thin film transistor of claim 12,
wherein the capacitor electrode includes a first capacitor electrode, and
wherein the first capacitor electrode is disposed on the floating electrode.

14. The thin film transistor of claim 12, wherein the capacitor electrode includes a second capacitor electrode, and the second capacitor electrode is disposed on a same layer as the gate electrode and spaced apart from the gate electrode.

15. The thin film transistor of claim 1, wherein the drain electrode, the source electrode and the floating electrode are disposed on a same layer.

16. The thin film transistor of claim 1, wherein at least a portion of the gate electrode overlaps the drain electrode, the source electrode, and the floating electrode.

17. A display apparatus including one or more thin film transistors, comprising:
a display panel including:
a gate electrode;
an active layer disposed on the gate electrode;
a drain electrode and a source electrode disposed on the active layer and spaced apart from each other; and
a floating electrode disposed between the drain electrode and the source electrode,
wherein the floating electrode includes a first opening portion and a second opening portion, and
wherein the first opening portion is configured to be opened toward the drain electrode, and the second opening portion is configured to be opened toward the source electrode.

18. The display apparatus of claim 17, wherein the active layer includes a channel portion including:
a first channel portion disposed, in a plan view, between the drain electrode and the first opening portion; and
a second channel portion disposed, in a plan view, between the source electrode and the second opening portion.

19. The display apparatus of claim 18, wherein the active layer further includes a first connecting portion disposed between the first channel portion and the second channel portion, and the first connecting portion is electrically connected with the floating electrode.

20. The display apparatus of claim 19,
wherein the active layer further includes a second connecting portion disposed at one side of the first channel portion and a third connecting portion disposed at one side of the second channel portion,
wherein the first channel portion is disposed between the first connecting portion and the second connecting portion, the second channel portion is disposed between the first connecting portion and the third connecting portion, and
wherein the second connecting portion is electrically connected with the drain electrode, and the third connecting portion is electrically connected with the source electrode.
